(19) United States
(12) Patent Application Publication
(10) Pub. No.: US 2011/0204483 A1
(43) Pub. Date: Aug. 25, 2011

(54) Electroluminescent device for the production of ultra-violet light

(76) Inventors: Patrick McNally, Dublin (IE); David Cameron, Majavesi (FI); Lisa O'Reilly, Wexford (IE); Gomathi Natarajan, Tamil Nadu (IN); Olabanji Francis Lucas, London (GB); Alec Reader, Southampton (GB)

(21) Appl. No.: 11/630,840

(22) PCT Filed: Jun. 27, 2005
(86) PCT No.: PCT/IE2005/000072

§ 371 Date: Apr. 8, 2011

(30) Foreign Application Priority Data
Jun. 25, 2004 (IE) 2004/0442

(51) Int. Cl. H01L 29/12; H01L 21/20

(52) U.S. Cl. 257/613; 438/478; 257/E21.09; 257/E29.068

(57) ABSTRACT

The invention provides a method of producing an opto-electronic device wherein a layer of lattice matched material is grown on a substrate, the lattice matched material being a cubic zincblend material and the substrate being a cubic diamond or zincblend material, to form a coated substrate.

### FIELD OF THE INVENTION

The present invention relates to an electroluminescent device and more particularly to electroluminescent device for the production of ultra-violet light and to methods of producing such devices.

### BACKGROUND TO THE INVENTION

An Electroluminescent device which emits light upon application of a suitable voltage to its electrodes is well known in the art. The electroluminescent device, including Light Emitting Diodes (LEDs) or Laser Diodes (LDs), fabricated from different semiconductors covers a broad range of wavelengths, from infrared to ultraviolet. In recent years, interest has focused on the production of blue and ultra-violet light emitting devices. The requirement for an electroluminescent device which emits light at the shorter blue or ultra-violet wavelength is desired as it completes the red, green and blue (RGB) primary colour family necessary for the generation of white light. The use of blue-emitting LEDs in addition with red and green emitting LEDs makes it possible to produce any colour in the visible light spectrum, including white.

To date the material of choice in the production of electroluminescent devices emitting blue or ultra-violet light consists of a number of variants of the group III-Nitrides. Due to their thermal stability, group-III nitride heterostructures provide suitable prerequisites for the fabrication of optoelectronic devices such as Light-Emitting-Diodes and Laser Diodes.

The ability to fabricate devices emitting in the blue-violet portion of the electromagnetic spectrum is the result of the large direct bandgap in these III-Nitride alloys (3-6 eV). These materials also possess high electron mobilities, high breakdown electric fields and good thermal conductivities. The use of these materials in electroluminescent devices has rapidly developed the production of high-brightness blue/green light emitting diodes (LEDs) with average lifetimes of ca. 10,000 hours. In addition, these materials were developed to display room temperature violet laser emission in AnGaN/GaN/AlGaN-based heterostructures under pulsed and continuous-wave (cw) operations [1-3]. However, these early devices were plagued by the presence of numerous threading dislocations (TDs), which impacted severely on the lifetimes and optical performance of laser diodes (LDs) in particular. These densities reached values as high as ˜10¹⁰ cm⁻², and were due mainly to the severe lattice mismatch between the substrate materials (e.g. 6H—SiC or α-Al₂O₃) and the grown III-Nitride epilayers (mismatches as high as 13.6% in the GaN/Al₂O₃ system [4]).

The manufacture of blue-violet light emitting devices is known, but high-performance devices have not yet been demonstrated due to problems such as lattice mismatching wherein the lattice sizes of the deposited semiconductor and the substrate are sufficiently different, that lattice defects cause significant amounts of energy to be thermalized. Lattice mismatch is the variance between the lattice spacings of the semiconductor and the substrate in which it is in contact. Lattice mismatch leads to the generation of misfit dislocations which are deleterious to the performance of the LED. Therefore there exists the need for an LED which overcomes this problem of lattice mismatch.

Lattice mismatch causes strain energy to build up in the semiconductor layer in contact with the substrate. The build up of strain during the growth of the lattice mismatched materials causes relaxation and the introduction of dislocations. The semiconductor layer in contact with the substrate undergoes substantial structural and/or morphological changes to relieve the strain. In recent years researchers have focused on the growth of graded buffer layers at the substrate/semiconductor layer in order to minimize dislocitions. However only limited success has been achieved and the defect density remains too high for operation of these devices.

Diode lasers are formed of structures that contain several thin layers of material of varying composition which are grown together. The growth is accomplished by carefully controlled epitaxial growth techniques. This technique deposits very thin layers of material of specified composition as single crystalline layers. Many electroluminescent devices known in the art comprise structures grown epitaxially in thin single crystal layers on lattice mismatched substrates and wherein the materials typically used are Al₂O₃ (sapphire) or SiC. For the most part researchers have concentrated on using III-V materials such as gallium arsenide (GaAs) to overcome the problem of lattice mismatch but have found device performance to be limited. These materials are lattice mismatched and adversely affect the performance of the light emitting device.

The recent introduction of epitaxial lateral overgrowth (ELOG) techniques [5-6] has facilitated the production of III-Nitride films with threading dislocation densities reduced by 3-4 orders of magnitude with respect to conventional metalorganic chemical vapour deposition techniques on both sapphire and SiC substrates. Studies of the optical properties of ELOG GaN and InGaN quantum wells [7-8] have revealed that TDs act as non-radiative recombination centres. The minority carrier diffusion length (<200 nm) is smaller than the average distance between the TDs, such that the emission mechanisms of the carriers that do combine radiatively appear to be unaffected by moderate TD densities (˜10⁶-10⁹ cm⁻²) [9]. However, reducing the TD density has been shown to reduce the reverse leakage current by ˜3 orders of magnitude in GaN p-n junctions [10], InGaN single [11] and multiple quantum well LEDs [12] and GaN/AlGaN heterojunction field effect transistors [9] fabricated on ELOG GaN. The use of ELOG GaN has also resulted in marked improvements in the lifetime of InGaN/GaN laser diodes [5]. Recently, other researchers have investigated the lateral growth of GaN films suspended from {11 2̅0} side walls of [0001] oriented GaN columns into and over adjacent etch walls using the Metal Organic Vapour Phase technique MOVPE technique, without the use of, or contact with, a supporting mask or substrate (as in ELOG) [13-14]. This technique has become known as pendeo-epitaxy and it also serves to reduce TD densities to 10⁴-10⁵ cm⁻²—many orders of magnitude lower, but still very high compared to mature technologies such as Si or GaAs.

In the past few years researchers have attempted to integrate III-Nitride epilayers with an Si substrate. One favoured substrate has been Si(111), as this surface has a 120° symmetry which is somewhat compatible with the hexagonal III-Nitrides, and Si possesses obvious advantages for compatibility with integrated devices and circuits, has good thermal conductivity and would be a low cost alternative [15-17]. This route is proving difficult, as the difference inlattice parameters and the strength of the Si—N bond prevent the formation of smooth, single crystal GaN on Si(111) [17-19]. To some extent this has been alleviated by using a two-step method involving various buffer layers such as SiC [20-21], GaN [19], AlN [22-24], GaAs [25], AlAs [26] and SiNₓ [27]. These typically yield smooth morphologies and columnar microstructures with a TD density of 10¹⁰-10¹¹ cm², displaying no real advance in TD density over previous devices. The principal weakness of these approaches lies in the fact that the additional heteroepitaxial layer does not necessarily alleviate mismatch problems due to the fundamental incompatibility of hexagonal III-Nitrides and cubic Si or GaAs.

The reduction of deleterious threading dislocations in wide-bandgap materials for optoelectronics devices is essential to their operation, and in particular to their longevity. The lattice mismatch between the substrate materials and the overgrown epilayers is the main culprit.

A new approach is required. One such approach is addressed by the present invention i.e the growth of cubic γ-CuCl (a wide- and direct-bandgap semiconductor) on low lattice mismatched cubic Si.

To date research on the cuprous halides has focused on three main thrusts over the past decade or so:
1. Spectroscopic and theoretical studies of band structures and exitonic-based luminescence in CuCl and CuBr [28-32].
2. Fundamental photoluminescence studies of CuCl quantum dots/nanocrystals embedded in NaCl crystals [33-35].
3. Fundamental surface studies of the growth mechanisms involved in the heteroepitaxy of CuCl single crystals on a number of substrates. Growth studies have involved the use of reflection high energy electron diffraction during molecular beam epitaxy of CuCl on MgO(001) [36-37], MgO(001) and CaF₂(111) [38] and on reconstructed (0001) haematite (α-Fe₂O₃) [39]. One recent study investigated the possibility of growing single crystals of CuCl using the sublimation of CuCl source powders or by reaction of Cu with HCl, and small (ca. 3 mm across) platelets were grown [40]. Finally, one group of researchers have examined the surface growth mechanisms in the heteroepitaxy of CuCl on both Si and GaAs substrates by molecular beam epitaxy [41]. Again, this study focussed on the fundamental physics of the island growth process and the nature of the interfacial bonding. No attempt has been made to move these studies into the realm of producing light emitting devices.

The problem remains of artificially coaxing an epitaxial layer onto an unsuitable substrate thus eliminating the undesirability of a lattice mismatch scenario.

U.S. Pat. No. 4,994,867 discloses the use of an intermediate buffer film having a low plastic deformation threshold. The intermediate buffer film is provided for absorbing defects due to lattice mismatch between a substrate and an overlayer. This patent differs from the present invention in that the present invention does not include a buffer layer. In the present invention the semiconductor layer is deposited directly on the surface of the substrate, this is made possible due to the compatability of the semiconductor layer/substrate lattice spacings.

### OBJECT OF THE INVENTION

It is an object of the present invention to reduce the above described disadvantages of lattice mismatch. Furthermore it is an object of the present invention to overcome the problem of lattice mismatch by artificially coaxing an epitaxial layer onto an otherwise unsuitable substrate.

It is also an object of the invention to produce an electroluminescent device capable of emitting blue or ultra-violet light.

In particular an object of the present invention is to grow an optoelectronic material on a silicon substrate, fabricate a light emitting electroluminescent device (ELD) on the prepared substrate and upon application of a suitable voltage to a pair of opposing electrodes to emit sub 400 nm ultra-violet light from the ELD.

It is an object of the present invention to grow a cubic zincblende material on a cubic diamond/zincblende substrate.

It is also an object of the present invention to reduce threading dislocations in electroluminescent devices.

Furthermore, it is an object of the present invention to manufacture an optoelectronic device emitting a blue-violet light where the thermalisation of energy is avoided or reduced and preferably where the device has a long lifespan.

It is an object of the present invention to fabricate an electroluminescent device from a wide-bandgap/direct band-gap material.

### SUMMARY OF THE INVENTION

According to the present invention there is provided a method for Manufacturing an electroluminescent device containing several thin layers of material of varying composition starting on a substrate of semiconductor material. Such layers are formed by an epitaxial growth technique. The present invention provides a method of producing an optoelectronic device wherein a layer of lattice matched material is grown on a substrate, the lattice matched material being a cubic zincblende material and the substrate being a cubic diamond or zincblende material to form a coated substrate.

The material used for the fabrication of the substrate may be selected from silicon, germanium, GaAs, Si:Ge:C, GaP, Al_xGa_(1-x)As, GaAs_(1-x)Sb_x, 3C—SiC (cubic SiC), Cubic BN, CuBr, CuCl, CuF and Cul, where x is the empirical ratio.

The lattice matched material may be a copper halide or a copper halide alloy. Preferably the copper halide or copper halide alloy may be selected from the group consisting of CuF, CuCl, CuBr or CuI or Cu(HaA)ₓ(HaB)_{y} where HaA and HaB are selected from F, Cl, Br or I and x and y are in the range zero or one. In a particularly preferred embodiment the copper halide is gamma-CuCl. The copper halide or copper halide alloy is deposited on a silicon substrate. In one preferred embodiment, the copper halide or copper halide alloy is deposited on the silicon substrate by thermal evaporation.

During the process for depositing the copper halide or alloy on the silicon substrate the halide may be sublimed and the resultant gas is deposited onto the silicon substrate. In particular, the gamma-CuCl is sublimed and the resultant CuCl gas is deposited onto the silicon substrate. Furthermore, the silicon substrate coated with the copper halide or copper halide alloy is annealed. In one preferred embodiment, the coated substrate is annealed at a temperature between 80° C.-175° C. for 5-30 minutes.

The coated substrate is then capped to prevent water absorption. Preferably, the coated substrate is capped with silicon dioxide.

The present invention also provides electroluminescent device having an ultra-violet light emission profile. Typically anything with a wavelength between 4 nm and 400 nm (nm=nanometer=10⁻⁹ m) is called UV light.

According to the present invention there is also provided a cubic diamond or zincblende wafer substrate having a cubic zincblende material deposited on at least one side thereof. The material used for the fabrication of the substrate may be selected from silicon, germanium, GaAs, Si:Ge:C, GaP, Al_xGa_(1-x)As, GaAs_(1-x)Sb_x, 3C—SiC (cubic SiC), Cubic BN, CuBr, CuCl, CuF and Cul, where x is the empirical ratio.

The cubic zincblende material may be a copper halide or a copper halide alloy. The copper halide or copper halide alloy may be selected from the group consisting of CuF, CuCl, CuBr or CuI or Cu(HaA)ₓ(HaB)_{y} where HaA and HaB are selected from F, Cl, Br or I and x and y are zero or one. Preferably, the copper halide is gamma-CuCl.

The present invention further provides for an electroluminescent device comprising a wafer substrate, coated with a lattice matched material, the substrate being a cubic diamond or zincblende material and the lattice matched material is a cubic zincblende material. The material used for the fabrication of the substrate is selected from silicon, germanium, GaAs, Si:Ge:C, GaP, Al_xGa_(1-x)As, GaAs_(1-x)Sb_x, 3C—SiC (cubic SiC), Cubic BN, CuBr, CuCl, CuF and Cul, where x is the empirical ratio. The cubic zincblende material may be a copper halide or a copper halide alloy.

The copper halide or copper halide alloy may be selected from the group consisting of CuF, CuCl, CuBr or CuI or Cu(HaA)ₓ(HaB)_{y} where HaA and HaB are selected from F, Cl, Br or I and x and y are in the range zero or one. The copper halide may be gamma-CuCl.

An electroluminescent device may comprise a wafer substrate having two sides and a copper halide or copper halide alloy deposited on one side thereof. In one preferred embodiment of the electroluminescent device, gamma-CuCl is deposited onto a silicon substrate. The coated substrate of the electroluminescent device is annealed.

The cuprous halides, e.g. CuCl, CuBr, CuI, are ionic I-VII compounds with the zincblende (T_{d}²;F 4̅3m) structure at room temperatures [32]. At room temperature, the prevalent phase of CuCl is called gamma-CuCl, which is a direct bandgap cubic semiconductor, with a bandgap of E_{G}=3.395 eV (λ˜365 nm—blue/violet light) and a lattice constant a_{CuCl}=0.541 nm [42-44]. As the lattice constant for zincblende GaAs is a_{GaAs}=0.565 nm (room temperature) and the lattice constant for cubic Si is aₛᵢ=0.543 nm (room temperature), the lattice misfit of CuCl is ˜4% with respect to (100) GaAs and is <0.4% with respect to (100) Si at room temperature [42]. This low mismatch, in particular with respect to Si, means that gamma-CuCl is suitable for low defect density heteroepitaxy on Si. The ionicity of CuCl is 0.75, while that of GaAs and Si is 0.31 and 0, respectively, so that gamma-CuCl on a GaAs is also a suitable combination of coating and substrate [41].

The melting point of gamma-CuCl is ˜430° C. and its boiling point is ˜1490° C. [42-44]. Since this melting point is significantly lower than that of Si (1414° C.), solid phase re-growth of gamma-CuCl on Si (and indeed also for GaAs) is also possible.

The copper halide may be deposited on the polished side of the prepared silicon substrate by various deposition means including by thermal evaporation means.

The coated substrate of the electroluminescent device may be capped to prevent water absorption. The capping layer of silicon dioxide is deposited over substantially all of the lattice matched layer. The capping of epiwafer is advantageous in that it prevents water absorption.

The electroluminescent device may include electrical contacts. An aluminium ohmic contact layer may be deposited on a one side of the silicon substrate wafer. The ohmic contact layer is deposited on the second side of the silicon substrate.

Electrical contacts are fabricated above the insulating or capping layer. The contacts may be semi transparent gold-contacts, although other suitable contacts known in the art could be used.

An advantage of having a layer configuration of a copper halide or copper halide alloy e.g. γ-CuCl deposited on one side of the silicon substrate and wherein the layer is deposited by the process of thermal evaporation and annealing is overcoming the undesirablility of lattice mismatch. The lattice spacing of γ-CuCl is such that it is matched or almost matched to Silicon. The γ phase is the cubic phase of CuCl, which can also appear in the hexagonal-symmetry phase known as “wurtzite”. The γ phase is a cubic, zincblende material with lattice constants very close to those of cubic silicon or cubic GaAs.

The device of the invention is a wide-bandgap, direct bandgap optoelectronic material. The direct bandgap material has holes and electrons positioned directly adjacent at the same momentum coordinates between layers thus allowing electrons and holes to recombine easily while maintaining momentum conservation. A semiconductor with a direct bandgap is capable of emitting light. A bandgap of approximately 3 eV is required in order for the production of blue and ultra-violet light emitting devices.

### BRIEF DESCRIPTION OF THE DRAWINGS

These and other features of the present invention will be better understood with reference to the following drawings in which:

FIG. 1 illustrates the layer structure of the electroluminescent device.

FIG. 2 illustrates the electroluminescent device with the application of an electrical potential difference across the device.

FIG. 3 illustrates the Fourier Transform Infrared Spectroscopy data for both Annealed and the Unannealed γ-CuCl/Si Films after 4 weeks.

### DETAILED DESCRIPTION OF THE DRAWINGS

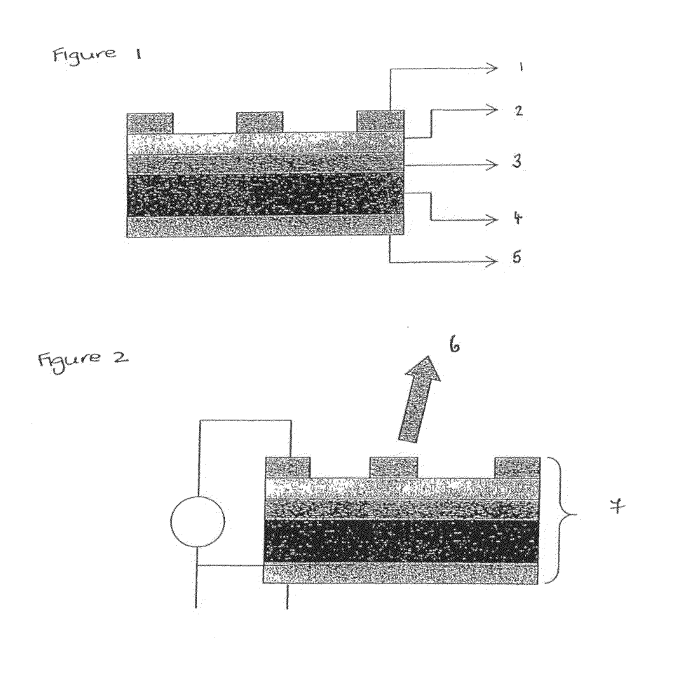

Referring to the drawings and specifically to FIG. 1 there is provided an electroluminescent device. The Electroluminescent device is composed of a number of layers of various materials. Viewing FIG. 1 from the top the structure comprises semi-transparent gold contacts (1), a layer of insulating or capping material (2), a luminescent layer (3), a silicon substrate (4) and an aluminium electrode (5).

In one embodiment of the invention the structure is fabricated through a number of separate procedures.

The first procedure is the substrate preparation procedure. A silicon sample with (100) or (111) orientation is used. The substrate is degreased by dipping in acetone, trichloroethylene and methanol, each for 5-10 minutes. The solvents were removed by dipping in deionised water for 5 minutes. The native silicon oxide was etched by dipping in a Hydrofluoric acid solution of five parts 48% HF and one part de-ionised water for 1 minute. The sample is then rinsed in deionised water, blow-dried using a Nitrogen gun and immediately loaded into the vacuum chamber of a resistive-boat thermal evaporator. Pure anhydrous CuCl powder is inserted in a quartz crucible before sealing the chamber and beginning pumping.

Another technique for depositing the copier halide on the silicon can include Molecular beam epitaxy. This can be used for the growth of of CuCl on both Si and GaAs substrates. The state-of-the art has not progressed much beyond the fundamental physics of the island growth process and the nature of the interfacial bonding [41].

The evaporation technique can also include depositing amorphous CuCl (a-CuCl) on an unheated substrate. A small evacuated chamber is used with a graphite heater stage centred therein A N₂ forming gas (no Hydrogen), or Ar, is used as ambient, and the sample (a-CuCl+Si) is slowly heated to temperatures within the range of typically 80° C.-175° C. for 5-30 minutes. As an alternative process, deposition is carried out on a heated substrate with the aim of achieving epitaxial growth in situ, without solid-state re-growth. Another technique for depositing the copper halide on the silicon can include the use of controlled RF or pulsed DC sputtering of CuCl.

The second procedure is the procedure for depositing the copper halide or copper halide alloy onto the surface of the silicon substrate. The system is ready for evaporation when the pressure reaches 10⁻⁵ mbar. CuCl is heated by resistive heating of the quartz crucible. The CuCl sublimes, the CuCl gas fills the chamber and is deposited onto the silicon substrate positioned above the crucible. Evaporation rates used range from 2 Å/sec to 150 Å/sec. CuCl thickness is typically around 500 nm. The structure is annealed at 100° C. for 5 minutes to develop a controlled of epitaxy γ-CuCl on the silicon substrate.

A N₂ forming gas (no Hydrogen), or Ar, is used as ambient, and the sample (a-CuCl+Si) is slowly heated to temperatures within the range of typically 80° C.-175° C. for 5-30 minutes. As an alternative process deposition may be carried out on a heated substrate with the aim of achieving epitaxial growth in situ without solid state re-growth.

The third procedure is the capping of γ CuCl/Si to prevent water absorption. The. γ-CuCl/Si films are immediately mounted on a spinner and a Borofilm® solution was used as the capping layer.

Borofilm and Phosphorofilm are solutions of boron and phosphorus containing polymers in water, fabricated by EMULSITONE COMPANY, 19 Leslie Court, Whippany, N.J. 07981, USA. These are also known as Spin-On Glasses (SOGs). When these solutions are applied to the silicon surface and heated to temperatures in the range 275° C.-900° C. for periods of approx. 5-15 minutes, a glass film forms in intimate contact with the silicon.

A few drops of Borofilm solution were placed upon the γ-CuCl/Si structure and varying spin rates were used to vary the capping layer thickness for both annealed and unannealed films. Typical rates vary from 500-5,000 rpm.

Fourier Transform Infrared Spectroscopy (FTIR) of the films was taken regularly on the bases of two times a week. The FTIR spectroscopy revealed the films were capped. Unannealed films tend to give better insulation/sealing. FIG. 3 shows the FTIR spectroscopy of both the annealed and the unannealed film (spin rate—500 rpm) after 4 weeks.

Furthermore the layers upon which an electrical potential difference is applied are deposited. The semi transparent gold contacts are applied to the structure above the insulating/capping layer and the luminescent layer. The Aluminium ohmic contact layer is deposited on the unpolished side of the prepared silicon substrate.

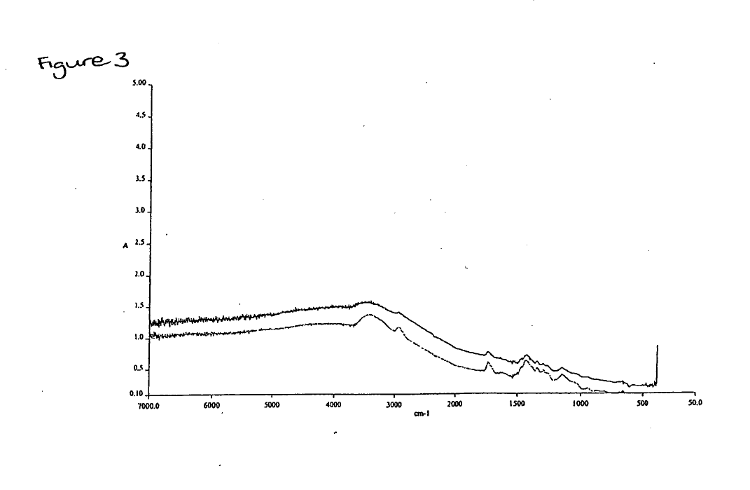

FIG. 2 illustrates ultra-violet light generation (6) from the electroluminescent device (7), the application of an electrical potential difference across the device resulting in an electric field, which promotes light emission through hot-electron impact excitation of electron-hole pairs in the γ-CuCl. Since the excitonic binding energy in this direct bandgap material is of the order of 300 meV at room temperature, the electron-hole recombination and subsequent light emission at ˜385 nm is mediated by excitonic effects.

The words “comprises/comprising” and the words “having/including” when used herein with reference to the present invention are used to specify the presence of stated features, integers, steps or components but does not preclude the presence or addition of one or more other features, integers, steps, components or groups thereof.

It is appreciated that certain features of the invention, which are, for clarity, described in the context of separate embodiments; may also be provided in combination in a single embodiment. Conversely, various features of the invention which are, for brevity, described in the context of a single embodiment, may also be provided separately or in any suitable subcombination.

The invention is not limited to the embodiments hereinbefore described but may be varied in both construction and detail.
1. (S. Nakamura and G. Fasol, The Blue Laser Diode—GaN based Light Emitters and Lasers, Springer, Berlin, 1997.
2. K. Itaya, M. Onomura, J. Nishino, L. Sugiura, S. Saito, M. Suzuki, J. Rennie, S. Numoue, M. Yamomoto, H. Fujimoto, Y. Kokubun, Y. Ohna, G. Hatakoshi and M. Ishikawa, Jpn. J. Appl. Phys., Part 1, 35, L1315 (1996).
3. G. E. Bulman, K. Doverspike, S. T. Sheppard, T. W. Weeks, H. S. Kong, H. M. Dieringer, J. A. Edmond, J. D. Brown, J. T. Swindell and J. F. Schetzena, Electron. Lett., 33, 1556 (1997).
4. “Growth and applications of III-Nitrides, O Ambacher, J. Phys. D: Appl. Phys., 31 2653-2710 (1998).
5. S. Nakamura, M. Senoh, S. Nagahama, N. Iwasa, T. Yamada, T. Matsushita, H. Kiyoku, Y. Sugimoto, T. Kozaki, H. Umemoto, M. Sano and K. Chocho, Appl. Phys. Lett., 72, 211 (1998).
6. T. Zheleva, O.-H. Nam, M. D. Bremser and R. F. Davis, Appl. Phys. Lett., 71, 2472 (1997).
7. J. A. Freitas, O.-H. Nam, R. F. Davis, G. V. Saparin and S. K. Obyden, Appl. Phys. Lett, 72, 2990 (1998).
8. X. Li, S. G. Bishop and J. J. Coleman, Appl. Phys. Lett., 73, 1179 (1998).
9. H. Marchand, N. Mang, L. Mao, Y. Golan, S. J. Rosner, G. Girolami, P. T. Fini, J. P. Ibbetson, S. Keller, S. DenBaars, J. S. Speck and U. K. Mishra, MRS Internet J. Nitride Semicond. Res., 4,2 (1999).
10. P. Kozodoy, J. P. Ibbetson, H. Marchand, P. T. Fini, S. Keller, S. P. Den Baars, J. S. Speck and U. K. Mishra, Appl. Phys. Lett., 73, 975 (1998).
11. T. Mukai, K. Tadekawa and S. Nakamura, Jpn. J. Appl. Phys., 37, L839 (1998).
12. C. Sasaoka, H. Sumakawa, A. Kimura, M. Nido, A. Usui and A. Sakai, J. Cryst. Growth, 189/190, 61 (1998).
13. T. S. Zheleva, S. A. Smith, D. B. Thomson, K. J. Linthicum, P. Rajagopal and R. F. Davis, J. Electron. Mater., 28, L5 (1999).
14. T. Gehrke, K. J. Linthicum, D. B. Thomson, P. Rajagopal, A. D. Batchelor and R. F. Davis, MRS Internet J. Semicond. Res., 4S1, G3.2 (1999).
15. A. Osinsky, S. Gangopadhyay, J. W. Wang, R. Gaska, D. Kuksenkov, H. Temkin, L K Shmagin, Y. C. Chang, J. F. Muth and R. M. kolbas, Appl. Phys. Lett., 72, 551 (1998).
16. K. S. Stevens, M. Kinniburgh and R. Beresfoid, Appl. Phys. Lett, 66, 3518 (1995).
17. T. L. Chu, J. Electrochem. Soc., 118, 1200 (1971).
18. H. M. Manasevit, F. M. Erdmann and W. I. Simpson, J. Electrochem. Soc., 118, 1864 (1971).
19. T. Lei and T. D. Moustakas, Mater. Res. Soc. Symp. Proc., 242, 433 (1992).
20. T. Takeiuchi, H. Amano, K. Hiramatsu, N. Sawaki and I. Akasaki, J. Cryst. Growth, 115, 634 (1991).
21. A. J. Steckl, J. Devrajan, C. Tran and R. A. Stall, Appl. Phys. Lett., 69,1264 (1996).
22. S. Guha and N. A. Bojarczuk, Appl. Phys. Lett, 72, 415 (1998).
23. P. Kung, A. Saxler, X. Zhang, D. Walker, T. C. Wang, I. Ferguson and M. Razeghi, Appl. Phys. Lett., 66, 2958 (1995).
24. M. Godlewski, J. P. Bergman, B. Monemar, U Rossner and A. Barski, Appl. Phys. Lett, 69, 2089 (1996).
25. J. W. Wang, C. J. Sun, Q. Chen, M. Z. Anwar, M. A. Khan, S. A. Nikishin, G. A. Seryogin, A. V. Osinsky, L. Chemyak, H. Temkin, C. Hu and S. Mahajan, Appl. Phys. Lett, 69, 3566 (1996).
26. N. P. Kobayashi, P. D. Dapkus, W. J. Choi, A. E. Bond, X. Zhang and D. H. Rich, Appl. Phys. Lett., 71, 3569 (1997).
27. Y. Nakada, I. Aksenov and H. Okumura, Appl. Phys. Lett., 73, 827 (1998).
28. M. Nakayama, A. Soumura, K. Hamasaki, H. Takeuchi and H. Nishimura, Phys. Rev. B, 55, 10099 (1997).
29. M. Nakayama, H. Ichida and H. Nishimura, J. Phys. Condens. Matter, 11, 7653 (1999).
30. B. Wyncke and F. Brehat, J. Phys. Condens. Matter, 12, 3461 (2000).
31. H. Heireche, B. Bouhafs, H. Aourag, M. Ferhat and M. Certier, J. Phys. Chem. Solids, 59, 997 (1998).
32. B. Bouhafs, H. Heirache, W. Sekkal, H. Aourag and M. Certier, Phys. Lett A, 240, 257 (1998).
33. Y. Masumoto and S. Ogasawara, J. Lumin., 87-89, 360 (2000).
34. M. Ikezawa and Y. Masumoto, J. Lumin., 87-89, 482 (2000).
35. J. Zhao, M. Ikezawa, A. V. Fedorov and Y. Masumoto, J. Lumin., 87-89, 525 (2000).
36. A. Yanase and Y. Segawa, Surf. Sci., 329, 219 (1995).
37. A. Yanase and Y. Segawa, Surf. Sci., 367, L1 (1996).
38. A. Yanase and Y. Segawa, Surf. Sci., 357-358, 885 (1996).
39. Q. Guo, L. Gui and N. Wu, Appl. Surf. Sci., 99, 229(1996).
40. C. T. Lin, E. Schönherr, A. Scluneding, T. Ruf, A. Göbel and M. Cardona, J. Cryst. Growth, 167, 612 (1996).
41. N. Nishida, K. Saiki and A. Koma, Surf. Sci, 324, 149 (1995).
42. H. G. Grahn, Introduction to Semiconductor Physics, World Scientific, 1999.
43. www.webelements.com
44. NIST Chemistry Webbook—webbook.nist.gov

1. A method of producing an optoelectronic device wherein a layer of lattice matched material is grown on a substrate, the lattice matched material being a cubic zincblende material and the substrate being a cubic diamond or zincblende material, to form a coated substrate.

2. A material as claimed in claim 1 wherein the substrate is selected from silicon, germanium, GaAs, Si:Ge:C, GaP, Al_xGa_(1-x)As, GaAs_(1-x)Sb_x, 3C—SiC (cubic SiC), Cubic BN, CuBr, CuCl, CuF and Cul, where x is the empirical ratio.

3. A method as claimed in claim 1 or claim 2 wherein the lattice matched material is a copper halide or a copper halide alloy.

4. A method as claimed in claim 3 wherein the copper halide or copper halide alloy is selected from the group consisting of CuF, CuCl, CuBr or CuI or Cu(HaA)ₓ(HaB)_{y} where HaA and HaB are selected from F, Cl, Br or I and x and y are zero or one.

5. A method as claimed in claim 4 wherein the copper halide is gamma-CuCl.

6. A method as claimed in claim 4 or claim 5 wherein the copper halide or copper halide alloy is deposited on the substrate.

7. A method as claimed in claim 6 wherein the copper halide or copper halide alloy is deposited on the substrate by thermal evaporation.

8. A method as 61aimed in claim 6 or 7, wherein the gamma-CuCl is sublimed and the resultant CuCl gas is deposited onto the substrate.

9. A method as claimed in any of claims 3 to 8 wherein the substrate coated with the copper halide or copper halide alloy is annealed.

10. A method as claimed in claim 9 wherein the coated substrate is annealed at a temperature between 80° C.-175° C. for 5-30 minutes.

11. A method as claimed in any preceding claim wherein the coated substrate is capped to prevent water absorption.

12. A method as claimed in claim 11 wherein the coated substrate is capped with silicon dioxide.

13. A cubic diamond or zincblende wafer substrate having a cubic zincblende material deposited on at least one side thereof.

14. A wafer substrate as claimed in claim 13 wherein the substrate comprises silicon, germanium, GaAs, Si:Ge:C, GaP, Al_xGa_(1-x)As, GaAs_(1-x)Sb_x, 3C—SiC (cubic SiC), Cubic BN, CuBr, CuCl, CuF and Cul, where x is the empirical ratio.

15. A wafer substrate as claimed in claim 13 or claim 14, wherein the cubic zincblende material is a copper halide or a copper halide alloy.

16. A wafer substrate as claimed in claim 15 wherein the copper halide or copper halide alloy is selected from the group consisting of CuF, CuCl, CuBr or CuI or Cu(HaA)ₓ(HaB)_{y} where HaA and HaB are selected from F, Cl, Br or I and x and y are zero or one.

17. A wafer substrate as claimed in claim 16 wherein the copper halide is gamma-CuCl.

18. An electroluminescent device comprising a wafer substrate, coated with a lattice matched material, the substrate being a cubic diamond or zincblende material and the lattice matched material is a cubic zincblende material.

19. A device as claimed in claim 18 wherein the substrate is selected from silicon, germanium, GaAs, Si:Ge:C, GaP, Al_xGa_(1-x)AS, As_(1-x)Sb_x, 3C—SiC (cubic SiC), Cubic BN, CuBr, CuCl, CuF and Cul, where x is the empirical ratio.

20. A device as claimed in claim 18 or claim 19 wherein the cubic zincblende material is a copper halide or a copper halide alloy.

21. An electro luminescent device as claimed in claim 20 wherein the copper halide or copper halide alloy is selected from the group consisting of CuF, CuCl, CuBr or CuI or Cu(HaA)ₓ(HaB)_{y} where HaA and HaB are selected from F, Cl, Br or I and x and y are zero or one.

22. An electroluminescent device as claimed in claim 21 wherein the copper halide is gamma-CuCl.

23. An electroluminescent device as claimed in any of claims 18 to 22 comprising a wafer substrate having two sides and a copper halide or copper halide alloy deposited on one side thereof.

24. An electroluminescent device as claimed in claim 23 wherein gamma-CuCl is deposited onto the substrate.

25. An electroluminescent device as claimed in any of claims 18 to 24 wherein the coated substrate is annealed.

26. An electroluminescent device as claimed in any of claims 18 to 25 wherein the coated substrate is capped to prevent water absorption.

27. An electroluminescent device as claimed in claim 26 wherein a capping layer of silicon dioxide is deposited over, substantially all of the lattice matched layer.

28. An electroluminescent device al claimed in any of claims 18 to 27 further comprising an aluminium ohmic contact layer deposited on one side of the substrate wafer.

29. An electroluminescent device as claimed in any of claims 18 to 28 further comprising electrical contacts.

30. An electroluminescent device as claimed in claim 29 wherein the contacts are gold.

31. An optoelectronic device whenever produced by a method as claimed in any of claims 1 to 12.

32. A substrate substantially as described herein with reference to the accompanying drawings.

33. An eleckoluminescent device substantially as described herein with reference to the accompanying drawings.
